(19) United States
(12) Patent Application Publication
(10) Pub. No.: US 2020/0227338 A1
(43) Pub. Date: Jul. 16, 2020

(54) MULTILAYERED THERMAL INTERFACE MATERIAL (TIM) WITH REDUCED THERMAL RESISTANCE

(71) Applicant: INTEL CORPORATION, Santa Clara, CA (US)

(72) Inventor: Shushan Gong, Phoenix, AZ (US)

(73) Assignee: INTEL CORPORATION, Santa Clara, CA (US)

(21) Appl. No.: 16/247,869

(22) Filed: Jan. 15, 2019

(51) Int. Cl. H01L 23/373; H01L 23/367; H01L 21/48; F28F 21/02; F28F 21/08

(52) U.S. Cl. CPC H01L 23/3735; H01L 23/3675; F28F 21/081; F28F 21/02; H01L 21/4882

(57) ABSTRACT

A multi-layered thermal interface material (TIM) suitable for integrated circuit (IC) die package assemblies. The multi-layered TIM may include at least a substrate material and an adhesion material. The substrate material may have high compressibility (low bulk modulus) and high thermal conductivity, such as a carbon-based material. The adhesion layer may be of a material suitable for sintering to a metallic package component, such as a heat spreader. The adhesion layer, once bonded to the package component, may reduce thermal resistance between an IC die and other portions of the package assembly. The adhesion material may be sintered with a heat spreader, for example. A low temperature bonding process may be employed to limit thermal exposure of an IC die. The adhesion material may comprise nanoparticles of elemental metal or metal alloy, which may be sprayed or printed onto a substrate material.

### BACKGROUND

In electronics manufacturing, integrated circuit (IC) packaging is a stage of semiconductor device fabrication, in which an IC that has been fabricated on a die (or chip) comprising a semiconducting material is encapsulated in an “assembly” or “package” that can protect the IC from physical damage and support electrical contacts that connect the IC to a host circuit board or another package. In the IC industry, the process of fabricating a package is often referred to as packaging, or assembly.

A number of IC packaging technologies include a heat spreader, which is to convey heat from an IC die to an external heat sink. The heat spreader is typically a bulk metallic component and not readily compressible, so a more compressible intermediary may be placed between the heat spreader and an IC die so as to improve thermal conductivity between the two even if there is some nominal non-planarity in either (or both) of the IC die surface and heat spreader. This intermediary is therefore often referred to as thermal interface material (TIM). A TIM may be in the form of viscous fluid, often referred to as a “thermal grease.” A thermal grease can offer good thermal conductivity, but often suffers from instability as the thermal cycles are experienced by the package assembly during IC operation. This instability typically leads to an increasing thermal resistance between the heat spreader and IC die over time.

An alternative TIM in the form of a solid pad comprises a material that is in a more stable solid/condensed phase, but still displays good thermal conductivity and is sufficiently compressible. While recent material advances may help TIM pads to become a robust thermal solution. The subset of TIM pads that offer the lowest thermal resistance interface when integrated in a package assembly will be the most commercially advantageous as they may enable longer IC assembly lifetimes in more extreme field environments, and/or higher IC assembly power densities, for example.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements. In the figures:

FIGS. 1A, 1B and 1C illustrate cross-sectional views of a multilayered TIM stack, in accordance with some embodiments;

FIG. 2 illustrates an isometric view of an IC assembly including a multilayered TIM pad, in accordance with some embodiments;

FIG. 3 illustrates a cross-sectional view of an IC assembly including a multilayered TIM pad, in accordance with some embodiments;

FIG. 4 illustrates a flow diagram of methods for assembling an IC assembly including a multilayered TIM pad, in accordance with some embodiments;

FIG. 5 illustrates a flow diagram of methods for fabricating a multilayered TIM pad, in accordance with some embodiments;

FIG. 6 is a functional block diagram of an electronic computing device, in accordance with some embodiments; and

FIG. 7 illustrates a mobile computing platform and a data server machine employing an IC assembly including a multilayered TIM pad, in accordance with some embodiments.

### DETAILED DESCRIPTION OF EXEMPLARY EMBODIMENTS

Embodiments are described with reference to the enclosed figures. While specific configurations and arrangements are depicted and discussed in detail, it should be understood that this is done for illustrative purposes only. Persons skilled in the relevant art will recognize that other configurations and arrangements are possible without departing from the spirit and scope of the description. It will be apparent to those skilled in the relevant art that techniques and/or arrangements described herein may be employed in a variety of other systems and applications other than what is described in detail herein.

Reference is made in the following detailed description to the accompanying drawings, which form a part hereof and illustrate exemplary embodiments. Further, it is to be understood that other embodiments may be utilized and structural and/or logical changes may be made without departing from the scope of claimed subject matter. It should also be noted that directions and references, for example, up, down, top, bottom, and so on, may be used merely to facilitate the description of features in the drawings. Therefore, the following detailed description is not to be taken in a limiting sense and the scope of claimed subject matter is defined solely by the appended claims and their equivalents.

In the following description, numerous details are set forth. However, it will be apparent to one skilled in the art, that embodiments may be practiced without these specific details. In some instances, well-known methods and devices are shown in block diagram form, rather than in detail, to avoid obscuring the embodiments. Reference throughout this specification to “an embodiment” or “one embodiment” or “some embodiments” means that a particular feature, structure, function, or characteristic described in connection with the embodiment is included in at least one embodiment. Thus, the appearances of the phrase “in an embodiment” or “in one embodiment” or “some embodiments” in various places throughout this specification are not necessarily referring to the same embodiment. Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

As used in the description and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items.

The terms “coupled” and “connected,” along with their derivatives, may be used herein to describe functional or structural relationships between components. It should be understood that these terms are not intended as synonyms for each other. Rather, in particular embodiments, “connected” may be used to indicate that two or more elements are in direct physical, optical, or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause an effect relationship).

The terms “over,” “under,” “between,” and “on” as used herein refer to a relative position of one component or material with respect to other components or materials where such physical relationships are noteworthy. For example in the context of materials, one material or material disposed over or under another may be directly in contact or may have one or more intervening materials. Moreover, one material disposed between two materials or materials may be directly in contact with the two layers or may have one or more intervening layers. In contrast, a first material or material “on” a second material or material is in direct contact with that second material/material. Similar distinctions are to be made in the context of component assemblies.

As used throughout this description, and in the claims, a list of items joined by the term “at least one of” or “one or more of” can mean any combination of the listed terms. For example, the phrase “at least one of A, B or C” can mean A; B; C; A and B; A and C; B and C; or A, B and C.

Described herein are examples of multilayered TIM stacks, which may be employed within a package assembly (e.g., single die, multi-die, 3D die stacks, etc.) in accordance with some embodiments. The inventor has determined that a significant factor in the thermal resistance of a package assembly is the thermal contact resistance of the TIM to one or more of the package components that the TIM is positioned between. Thermal contact resistance of a TIM is in part a function of the package components with which the TIM is integrated, and therefore TIM thermal conductivity is not in itself determinative of package thermal resistance. Thermal contact resistance of a TIM to a first component on one side of the TIM may be superior (i.e., lower) to the thermal contact resistance of the TIM to a second component on an opposite side of the TIM. For example, where a TIM is designed to provide low thermal contact resistance with an IC die on one side of the TIM, that TIM may display high thermal contact resistance to a heat spreader and/or heat sink on an opposite side of the TIM. The multilayered TIM stacks described herein may allow for a first material layer of the stacks to be optimized for low contact resistance to a first component on one side of the TIM, while a second material layer of the stacks may be further optimized for low contact resistance to a second component on the opposite side of the TIM. With the design of the first and second material layers less constrained by demands on the other, lower thermal contact resistance may be achieved in a package assembly that displays a lower effective thermal resistance. A low thermal contact resistance between material layers of a multilayered TIM stack may be achieved through selection of the materials as well as through the fabrication techniques enlisted to form the multilayered TIM stack, which may be performed independent of an IC package assembly process.

In accordance with some embodiments, a TIM stack comprises a first material, and a second material over at least one side of the first material. In some embodiments described further below, the second material has a low melting temperature, and wets another TIM material surface well, and/or also wets a package component (e.g., a heat spreader or heat sink) surface, accommodating (e.g., filling in) surface roughness in the mating surface. In some other embodiments described further below, the second material sinters with a mating material (e.g., package components such as a heat spreader or heat sink surface), and/or physically bonds with the other TIM.

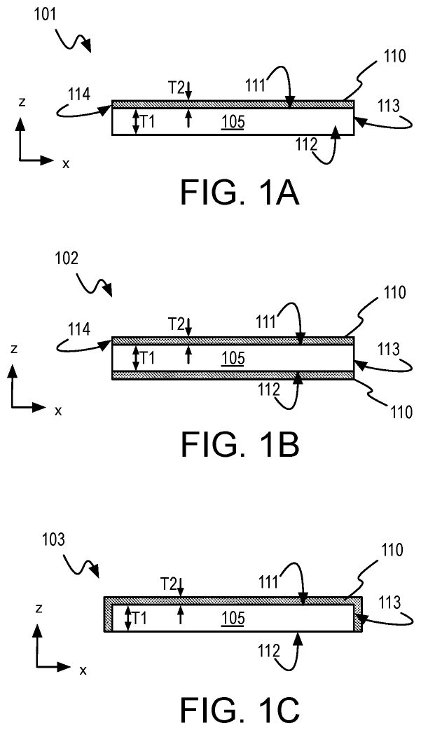

FIGS. 1A, 1B and 1C illustrate cross-sectional views of a multilayered TIM stack, in accordance with some embodiments. In the example shown in FIG. 1A, a TIM stack 101 includes a material 105, and a material 110 over a surface 111 of material 105. Surface 111 has an area (e.g., X-Y plane) that defines a footprint of a dimensionalized pad comprising TIM stack 101. The footprint of TIM stack 101 may be any size suitable for a given IC package assembly. For example, TIM stack 101 may have a footprint of a few square millimeters sufficient for contacting a small IC die, up to around 1000 mm², sufficient for contacting the majority of a large IC die surface, or multiple IC die surfaces, etc. In the illustrated example, material 110 is only over the single surface 111, and is absent from a surface 112 that is on a side of material 105 opposite surface 111. Material 110 is likewise absent from a sidewall 113 of material 105. As further illustrated, material 110 covers the entire area of surface 111 such that material 110 has substantially the same footprint as material 105. In the illustrated examples, material 110 is in direct contact with material 105. In other embodiments however, one or more intervening materials may be between material 110 and material 105. In the example of FIG. 1A, material 110 has a sidewall 114 that intersects sidewall 113. As described further below, presence of material 110 on only one side of material 105, and/or the precise alignment of sidewalls 113 and 114 may be indicative of the fabrication technique(s) employed to form TIM stack 101.

In the example illustrated in FIG. 1B, TIM stack 102 includes material 110 on two sides of material 105. In this example, material 110 is over the two opposing surfaces 111 and 112. In this example, for each material 110, sidewall 114 again intersects sidewall 113. Material 110 is again in direct contact with material 105. As described further below, the presence of material 110 on two sides of material 105, and/or the precise alignment of sidewalls 113 and 114 may again be indicative of the fabrication technique(s) employed to form TIM stack 102. In the example illustrated in FIG. 1C, TIM stack 103 includes material 110 on one side of material 105, with material 110 wrapping around sidewall 113. In this example, material 110 is again in direct contact with material 105. As described further below, the presence of material 110 on only one side of material 105, and/or the encapsulation of sidewall 113 may again be indicative of the fabrication technique(s) employed to form TIM stack 103.

As further illustrated in FIG. 1A-1C, material 105 has a material thickness T1 in a dimension (e.g., z-dimension) that is orthogonal to surface 111 and/or 112. Material 110 has a material thickness T2. In some exemplary embodiments, material thickness T1 is significantly greater than material thickness T2. Material thickness T1 may span a first range, for example to achieve some minimal stand-off height between two components of an IC package assembly sufficient for accommodating irregularities in one or more of the IC package components. In some examples, material thickness T1 is more than 25 μm, advantageously at least 50 μm, more advantageously at least 100 μm, and may be as much as 1000 μm.

Noting that one or more of the IC package assembly components to which TIM stack 101 is to interface may have one or more of thickness non-uniformity, surface non-planarity, and/or surface roughness, material 105 may advantageously have a relatively low bulk modulus that, when coupled with sufficient material thickness T1, will enable material 105 to compress under load, accommodate irregularities between opposing package components, and maximize the area of physical contact between the components. In some examples, material 105 is of a composition having a bulk modulus below 1 GPa, and advantageously below 100 MPa.

Material 105 may have a variety of compositions. In some embodiments, material 105 is carbon-based or “carbonaceous” as carbon has been found to have good thermal conductivity, stability, and compatibility with IC die. In some embodiments, material 105 is a composite comprising one or more fillers in a matrix. In some such embodiments, at least one of the fillers and matrix is nonmetallic, and advantageously carbonaceous. In some specific embodiments, the filler comprises a graphitic material (e.g., crystalline graphite, pyrolytic graphite). Graphite offers high thermal conductivity (e.g., more 10 Wm⁻¹K⁻¹). Graphitic structures within a matrix may also have a low bulk modulus, displaying high compressibility (e.g., 40%, or more) at typical application pressures. The graphitic material may be in any form, such as a stack of 2D sheets oriented either to be parallel to material thickness T1, orthogonal to material thickness T1, or non-parallel/non-orthogonal material thickness T1. The graphitic material may also be in the form of nanotubes (e.g., with longitudinal lengths extending predominantly in the z-dimension). For such embodiments, the matrix material may be a polymer. While many polymers may be suitable, some examples include silicone-based polymers (i.e., polysiloxanes comprising silicon, oxygen, carbon), synthetic rubber, and natural rubber. Advantageously, the polymer has high temperature stability (e.g., suitable for temperatures of 150° C., or more).

In further reference to FIG. 1A-1C, material thickness T2 may span a second range, for example just sufficient to achieve some beneficial reduction in thermal contact resistance to a component of an IC package assembly. Thickness T2 need not accommodate package component irregularities (particularly where thickness T1 accommodates such irregularities), and may therefore be significantly thinner than material thickness T1. As such, material 105 may be considered a “substrate” or “base” material of a TIM stack, while material 110 may be considered a “coating” over the TIM substrate. In some examples, material thickness T2 is one or more orders of magnitude smaller than material thickness T1. In some further examples, material thickness is at least a few tens of nanometers (e.g., 40-50 nm), which is usually sufficient to ensure a continuous coating (e.g., no pinholes) over material 105 and/or to ensure there is enough material 110 to sinter with a package component, for example as described further below. The thermal resistance of a TIM stack attributable to material 110 may be minimized with a minimal material thickness T1. Hence, in some further embodiments, material thickness T2 is less than 10 μm, advantageously less than 5 μm, and more advantageously less than a few hundred nanometers (e.g., less than 300 nm).

Material 110 may have nanostructure. A material with nanostructure has structural features with a nanoscale length (e.g., less than 1000 nm). Such nanostructure may facilitate low thermal contact resistances and/or facilitate sintering with IC package components. Nanostructure may also enable material 110 to better accommodate roughness in a mating surface of a package component. In some nanostructured embodiments, material 110 comprises a plurality of (nano)particles that, over some sample population, has an average diameter less than 200 nm, and advantageously between 10 and 50 nm. Depending on composition (and/or the formation process), material 110 may have a topology characterized by an extreme aspect ratio (e.g., a nanoforest) in which the nanostructures have longitudinal lengths that predominantly extend away from surface 111 and/or surface 112.

In some embodiments, material 110 is of a composition that has a higher bulk modulus than that of material 105. Noting that material thickness T2 may be very small, a bulk modulus of material 110 may not be directly determinable for a TIM stack. However, where the composition of material 110 is determined, for example though elemental analysis of a TIM stack, the bulk modulus for that material composition in a bulk state may be indirectly compared to that of material 105. In some examples, material 110 has a composition associated with a bulk modulus over 10 GPa, and may be 20-30 GPa, or more.

Wherein material 105 is carbon-based, material 110 may be other than carbon-based. In some such embodiments material 110 is metallic, comprising an elemental metal, or a metal alloy. Many metals and metal alloys have good thermal conductivity, and it may be possible to utilize any number of them as material 110. In some embodiments, material 110 is of a composition that will melt at some low temperature compatible with a package assembly process. For example, material 110 may be a metal that will melt at a temperature of 200° C. or below, which may enable material 110 to wet a package component during the package assembly process. In some other embodiments, material 110 is of a composition that will sinter with a package component at some temperature compatible with a package assembly process. Sintering entails solid state diffusion of one material into another, which can occur at temperatures below the material melting point. In some examples, material 110 sinters with at least one of Ni, Cu, Ag, or Au at less than 300° C., advantageously less than 200° C., and more advantageously less than 150° C. As described further below, a low sintering temperature may be advantageous during an IC assembly process, enabling a low thermal resistance without excessive heat cycling of an IC die and/or other components of an IC package assembly. The elements Ni, Cu, Ag and Au are provided as examples of materials that may be employed in an IC package component, such as a heat spreader or heat sink. However, where the package component is to comprise some alternative, material 110 is to advantageously sinter with that alternative at again less than 300° C., advantageously less than 200° C., and more advantageously less than 150° C.

In some specific examples, material 110 comprises at least one of Au, Ag, In, Bi, Ga, or Sn. In some such embodiments, material 110 comprises predominantly one of Au, Ag, In, Bi, Ga or Sn. These exemplary metals offer the advantages of either becoming liquidous at relatively low temperatures and capable of then wetting a number of substrate materials, such as one or more of Ni, Cu, Ag, and Au; or being capable of sintering at relatively low temperatures with a number of other materials, such as one or more of the Ni, Cu, Ag, and Au listed above. These metals also display high thermal conductivity. One or more of these metals are also resistant to oxidation and/or their oxides readily decompose (e.g., thermally), facilitating their bond with a mating component. One or more of these metals may also be deposited in a manner that generates nanostructure within material 110, which as noted elsewhere may facilitate low thermal contact resistance.

Material 110 may interface with material 105 through one or more of physisorption (van der Waals force), electrostatic binding, or through charge-transfer interactions and chemisorption. Depending on the character of these interface interactions, thermal contact resistance at the interface between material 110 and material 105 may be more or less as greater interactions tend to favor low thermal contact resistance. As such, compositional compatibility of materials 105 and 110, as well as techniques to fabricate TIM 101, may be selected so as to favor strong interactions between materials 105 and 110.

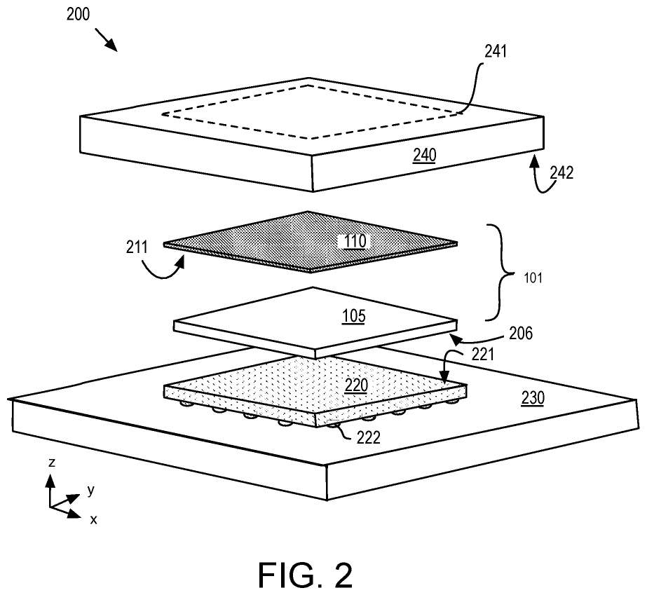

FIG. 2 illustrates an exploded isometric view of an IC package assembly 200 including a multilayered TIM pad, in accordance with an embodiment. IC package assembly 200 includes a substrate 230, which may be any package substrate or a circuit board that may further include any number of conductive routing layers (not depicted). As further illustrated in FIG. 2, an IC die 220 is connected to substrate 230 by conductive interconnects 222. Conductive interconnects 222 may be any known to be suitable for electrically coupling an IC die, such as, but not limited to, solder features (e.g., solder balls, solder bumps, microbumps, pillars, etc.). IC die 220 may include one or more ICs, such as, but not limited to, power management ICs (PMICs), radio frequency communication ICs (RFICs), microprocessors (e.g., application processors, central processors, graphics processors), memory ICs (e.g., DRAM), or System on a Chips (SoCs) that may include two or more of these types of ICs, etc. In the illustrated example, only one IC die 220 is illustrated, however more than one such IC die may be interconnected to substrate 230.

In embodiments, a package assembly further includes a multilayered TIM stack. As shown in FIG. 2, IC package assembly 200 further includes multi-layered TIM stack 101. TIM stack 101 includes material 105 and material 110, each of which may have any (or all) of the attributes described above. Other package assembly embodiments may include TIM stack 102 or 103, for example. In the example illustrated in FIG. 2, material 110 is between material 105 and an integrated heat spreader (IHS) 240. Material 105 is therefore located between material 110 and IC die 220. Depending on the technique employed to assemble package assembly 200, the footprint of TIM stack 101 may be larger than the footprint of IC die 220, smaller than the footprint of IC die 220, or equal to the footprint of IC die 220. In the exemplary embodiment illustrated, IC die 220 has a top surface 221 with a first area (x-y plane). Material 105 has a second surface 206 with a second area (x-y plane) that is smaller than the first area, for example to allow for misalignment between TIM stack 101 and IC die 220. Material 110, has a third surface 211 that is in contact with material 105. In some exemplary embodiments, third surface 211 has a third area that is no smaller than the second area, and may be substantially equal to the second area. IHS 240 has a fourth surface 242 that is larger than the third area (denoted by dashed line 241) allowing for sidewall portions of IHS 240 to enclose IC die 220 and TIM stack 101.

IHS 240 may be of one or more materials having sufficient thermal conductivity, and may have any thickness suitable to provide sufficient package rigidity and/or protection to the underlying IC die 220 and TIM stack 101. Dashed line 241 demarks an interior region of IHS 240 that is in contact with TIM stack 101, and more specifically in direct contact with material 110. As shown, heat spreader 240 further includes an exterior wall portion beyond dashed line 241, which includes a contact surface 242 that is affixed to substrate 230, for example with an adhesive sealant (not depicted) that forms a perimeter around IC die 220.

In some embodiments, there is a bond between a TIM stack and an IC package component. The inventor has found that bonding between a TIM stack and an IC package component will reduce thermal contact resistance associated with the TIM/component interface. One characteristic indicative of bonding is adhesion strength and experiments with candidate TIM materials that displayed higher adhesion and displayed lower thermal contact resistance. The bond may comprise material in the TIM stack sintered with material of the component, and hence one advantage of including a sinterable adhesion layer of the TIM stack over a base, or substrate material.

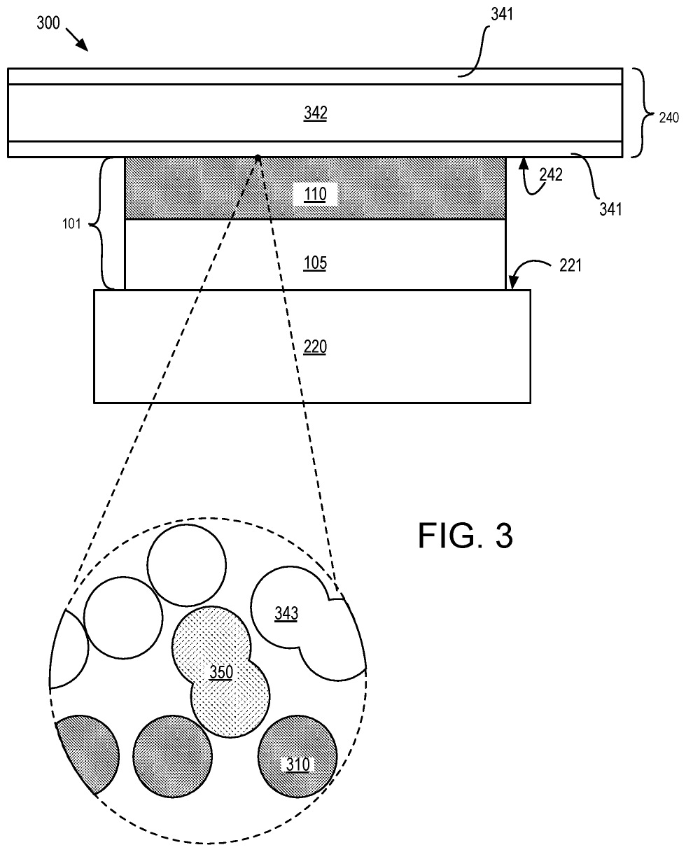

FIG. 3 illustrates a cross-sectional view of an IC assembly 300 including multilayered TIM pad 101 in which material 110 is bonded to IHS 240, in accordance with some embodiments. The bonding between material 110 and IHS 240 will result in a higher adhesion strength than if IHS 240 instead interfaced directly to material 105. Along with higher adhesion strength, thermal contact resistance between material 110 and IHS 240 will be lower than if material 105 interfaced directly to material 110. Assuming material 110 has sufficiently high thermal conductivity, and sufficiently low thermal contact resistance with material 105, the lower thermal contact resistance between IHS 240 and material 110 will result in a lower thermal resistance for assembly 200. As shown, heat spreader 240 comprises a bulk material 342 and a finish material 341 over bulk material 342. In one example, bulk material 342 comprises at least Cu, and may advantageously be an alloy thereof (e.g., that is predominantly Cu). Finish material 341 may comprise one or more thermally conductive materials suitable for passivating bulk material 342, such as a metal (elemental or alloy) that resists oxidation. Where bulk material 342 comprises Cu, finish material 341 comprises other than Cu and in some examples comprises Ni, and may be predominantly Ni. Finish material 341 may have a thickness of a few microns, for example, and have a relatively high RMS roughness value as a result of the finishing process (e.g., electrolytic or electroless plating).

In some advantageous embodiments, at least finish material 341 is sintered with material 110. As further illustrated in the expanded view of FIG. 3, material 110 includes particles 310, which may have nanometer dimensions. Nanostructure may also enable material 110 to better accommodate the surface roughness finish material 341, increasing the effective area where close particle interactions may occur. In the example shown in FIG. 3, finish material 341 includes particles 343. The sintered joint of material 110 to finish material 341 includes fused particles 350 that comprise both atoms of finish material 341 and atoms of material 110. Absent sintering, there would be no such particle fusion/bonding, and all particles 343 would instead remain separate from particles 310 at the interface surface 242 and material 110. Hence, fused particles 350, which may be visible through cross-sectional transmission electron microscopy (TEM), are indicative of a bonded TIM-IHS interface in accordance with some embodiments. Although fused particles analogous to fused particles 350 may also be present at the interface between material 110 and material 105, such fused particles may also be absent from the interface between material 110 and material 105 as the interface between material 110 and material 105 may be characterized by one or more of physisorption, electrostatic binding, or charge-transfer interactions. An analog to fused particles 350 may also be absent from the interface between material 105 and surface 221. Here too however, one or more of physisorption, electrostatic binding, or charge-transfer interactions may occur as the surface 221 may be a mirror polish having very low RMS surface roughness and comprising a material (e.g., crystalline silicon) that has good phonon coupling with material 105 (e.g., graphite).

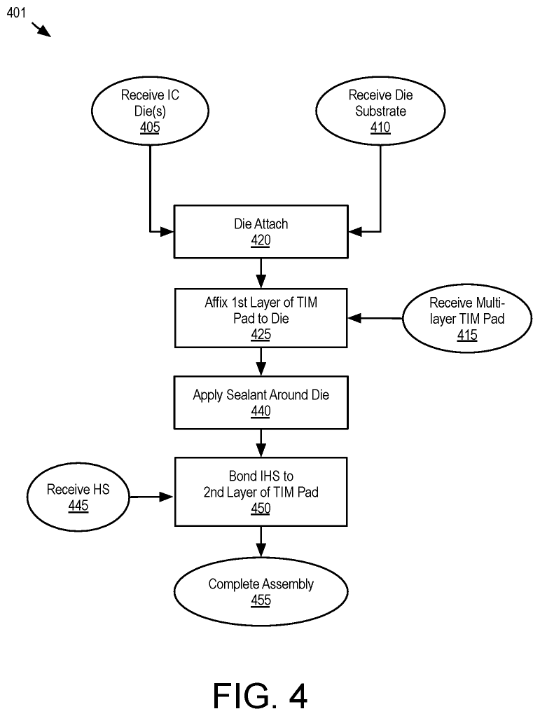

FIG. 4 illustrates a flow diagram of methods 401 for assembling an IC assembly including a multilayered TIM pad, in accordance with some embodiments. An embodiment of methods 401 may be employed to generate the IC package assembly 200, for example. Methods 401 begin at block 405 where an IC die is received, for example from a IC chip or wafer manufacturer. At block 410, an IC die substrate and/or interposer is received, for example from a package substrate or printed circuit board (PCB) supplier. At block 420, an IC die is attached to a die substrate with any die attach technique known in the art. In one example, a flip chip process is employed at block 420. In another example, a chip scale package (CSP) process is employed at block 420.

Methods 401 continue at block 415 where a multi-layered TIM pad is received, for example from a supply chain vendor. At block 425, a first material layer of the TIM pad is affixed to the die with any technique known to be suitable in the art. In some examples, a TIM pad is affixed by a pick and place machine. In other examples, a reel-to-reel process is employed. Methods 401 continue at block 440, where a bead of sealant is applied to the die substrate around a perimeter of the IC die. Any sealant extrusion/application process known in art may be employed at operation 440. Notably, ordering of the blocks illustrated in FIG. 4 may vary with implementation. For example, blocks 440 and 425 may be such that operations associated with block 440 are performed prior to performing operations associated with block 425.

At block 445 a heat spreader is received, for example from a supply chain vendor. The heat spreader may, for example, be a stamped sheet good, such as a plated metal that has been formed into a lid of predetermined dimensions.

At block 450, the heat spreader is brought into contact with a second material layer of the TIM pad, for example with a pick-and-place machine that compresses the heat spreader against the TIM pad and sealant bead. In some exemplary embodiments block 450 further comprises a thermal cycle sufficient to melt or sinter at least a portion of the second material of the TIM pad with a surface of the heat spreader, in some cases forming a metallurgical bond between the two. In some advantageous embodiments, block 450 comprises a compression bonding process during which the TIM pad and/or heat spreader is heated to a temperature of at least 100° C. In some such embodiments, the TIM pad and/or heat spreader are heated to no more than 300° C., advantageously no more than 200° C., and more advantageously no more than 150° C. In one specific example where the TIM pad includes an adhesion layer comprising Ag (which may further have nanostructure), a thermal cycle between 250° C. and 300° C. may sinter Ag particles to Ni particles of a heat spreader with a Ni surface finish. In another specific example where the TIM pad includes an adhesion layer comprising Au (which may further have nanostructure), a thermal cycle between 150° C. and 250° C. may sinter Au particles to Ni particles of a heat spreader with a Ni surface finish. Other embodiments may sinter or melt any of In, Bi, Ga, or Sn over a similar temperature range. During the thermal cycle at block 450, a compressive force (e.g., 200-500 kPa) may be maintained to ensure a material layer of the TIM pad is in intimate contact with a material surface of the heat spreader. Once the heat spreader is joined and, having become an integrated heat spreader (IHS) that is integrated into the package assembly, methods 401 may proceed with any techniques known in the art to complete the package assembly at block 455.

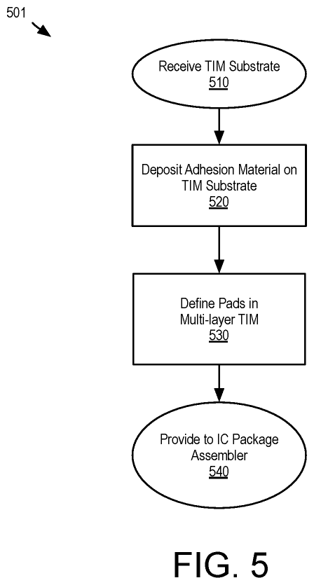

FIG. 5 illustrates a flow diagram for methods 501 for fabricating a multilayered TIM pad, in accordance with some embodiments. An embodiment of methods 501 may be employed to generate the TIM stack 101 (FIG. 1A), for example, to provide a pad suitable for input into methods 401. Methods 501 begin at operation 510 where a TIM substrate or base material is received, for example from a supplier in the form of a sheet good. The base material may have any of the attributes described above for material 105 in the context of TIM stack 101, for example. In some carbon-based examples where the substrate or base material comprises a graphitic filler in a polymer matrix, commercial sources include Panasonic Corporation of North America, and Hitachi Chemical, Corp. Alternatively, the TIM substrate or base material may be formed or fabricated in-house at operation 510.

Methods 501 continue at block 520 where an adhesion material is deposited on the base material. The adhesion material may have any of the attributes described above for material 110 in the context of TIM stack 101, for example. Deposition of the adhesion material may be by any technique known to be suitable for the material, such as, but not limited to liquid phase deposition (e.g., jet printing or spraying) techniques, solid phase deposition techniques (e.g., sputtering), or vapor phase deposition techniques (e.g., chemical vapor deposition), or gas phase deposition techniques (e.g., atomic layer deposition). In some examples where a material is to be deposited upon a carbon-based substrate, an ink comprising nanoparticles of one or more metals (e.g., Ag) is deposited at block 520. Any jetting process known to be suitable for spraying such an ink may be employed at block 520. Conditions at block 520 may be any known to be suitable for achieving desired film adhesion and morphology. For example, block 520 may entail a thermal cycle, which need only be limited by the stability of the base material.

Methods 501 continue at block 530 where pads are defined in the multi-layered TIM stack. Any die stamping process, laser ablation, water jet patterning process may be employed at block 530 to separate a sheet good generated at block 520 into pad having a predetermined footprint. For such embodiments, the adhesion material deposited at block 520 may be expected to have precisely the same footprint as that of the substrate as the two material layers are defined concurrently by a single patterning process at block 530. Notably, no order is implied in methods 501, and block 530 may instead be prior to block 520. For example, a TIM substrate material may be first patterned into predetermined pads at block 530, and adhesion material then deposited over the TIM pad. For such embodiments, the adhesion material deposited at block 520 may be expected to land on any exposed surface of the substrate material, including a sidewall of the substrate material. Furthermore, the adhesion material may be deposited on multiple sides of a substrate material regardless of whether a TIM pad is patterned before or after the application of an adhesion material. Methods 501 then complete at block 540 where the pad comprising a multilayered TIM stack is provided to an IC package assembler.

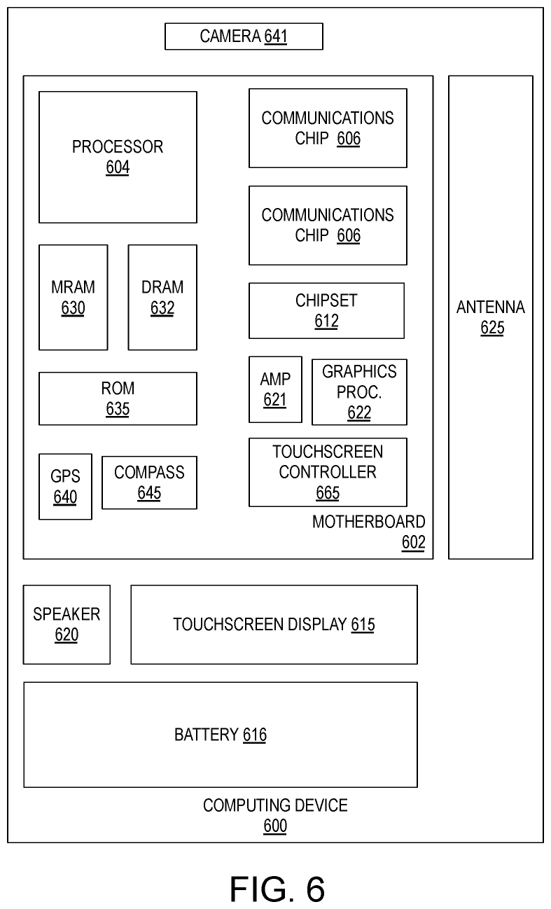

FIG. 6 is a functional block diagram of an electronic computing device 600, in accordance with an embodiment of the present invention. Device 600 further includes a motherboard 602 hosting a number of components, such as, but not limited to, a processor 604 (e.g., an applications processor). Processor 604 may be physically and/or electrically coupled to motherboard 602. In some examples, processor 604 includes an integrated circuit die packaged with a multi-layered TIM stack, which may be further bonded to an IHS. In general, the term “processor” or “microprocessor” may refer to any device or portion of a device that processes electronic data from registers and/or memory to transform that electronic data into other electronic data that may be further stored in registers and/or memory.

In various examples, one or more communication chips 606 may also be physically and/or electrically coupled to the motherboard 602. In further implementations, communication chips 606 may be part of processor 604. Depending on its applications, computing device 600 may include other components that may or may not be physically and electrically coupled to motherboard 602. These other components include, but are not limited to, volatile memory (e.g., DRAM 632), non-volatile memory (e.g., ROM 635), flash memory (e.g., NAND or NOR), magnetic memory (MRAM 630), a graphics processor 622, a digital signal processor, a crypto processor, a chipset 612, an antenna 625, touchscreen display 615, touchscreen controller 665, battery 616, audio codec, video codec, power amplifier 621, global positioning system (GPS) device 640, compass 645, accelerometer, gyroscope, speaker 620, camera 641, and mass storage device (such as hard disk drive, solid-state drive (SSD), compact disk (CD), digital versatile disk (DVD), and so forth), or the like. In some exemplary embodiments, at least one of the functional blocks noted above comprise an IC package assembly including a TIM stack, for example as described elsewhere herein. The TIM stack may further comprise a component bonded to a surface material of the TIM stack, such as an IHS.

Communication chips 606 may enable wireless communications for the transfer of data to and from the computing device 600. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. Communication chips 606 may implement any of a number of wireless standards or protocols, including but not limited to those described elsewhere herein. As discussed, computing device 600 may include a plurality of communication chips 606. For example, a first communication chip may be dedicated to shorter-range wireless communications, such as Wi-Fi and Bluetooth, and a second communication chip may be dedicated to longer-range wireless communications such as GPS, EDGE, GPRS, CDMA, WiMAX, LTE, Ev-DO, and others.

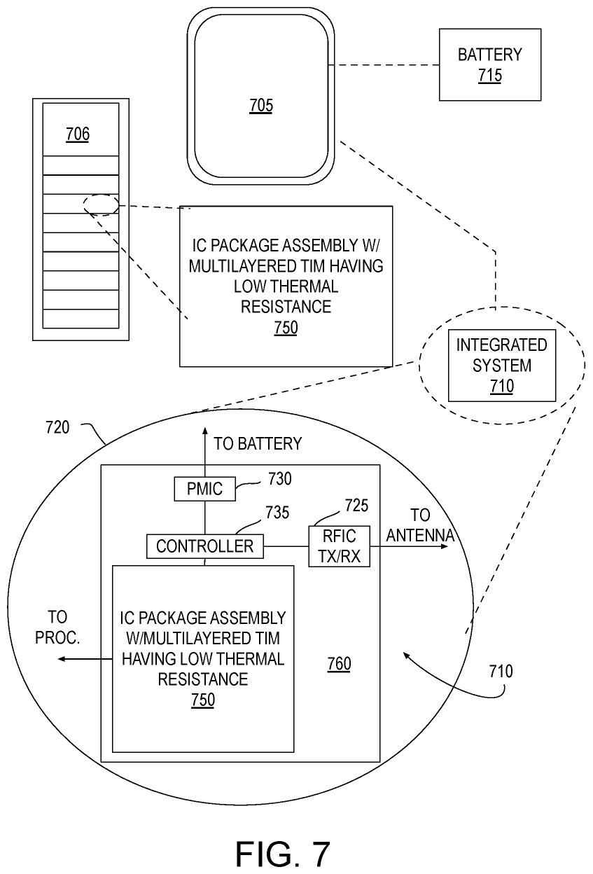

FIG. 7 illustrates a mobile computing platform and a data server machine employing a IC package assembly including a multi-layered TIM, for example as described elsewhere herein. In some further embodiments, a material layer of the TIM is bonded to a component of the package assembly, such as an IHS. Computing device 600 may be found inside platform 705 or server machine 706, for example. The server machine 706 may be any commercial server, for example including any number of high-performance computing platforms disposed within a rack and networked together for electronic data processing, which in the exemplary embodiment includes a packaged SoC 750 that further includes a TIM stack, which may be further bonded to a heat spreader, for example as described elsewhere herein. The mobile computing platform 705 may be any portable device configured for each of electronic data display, electronic data processing, wireless electronic data transmission, or the like. For example, the mobile computing platform 705 may be any of a tablet, a smart phone, laptop computer, etc., and may include a display screen (e.g., a capacitive, inductive, resistive, or optical touchscreen), a chip-level or package-level integrated system 710, and a battery 715.

Whether disposed within the integrated system 710 illustrated in the expanded view 720, or as a stand-alone chip within the server machine 706, IC package assembly 750 may include TIM stack, for example as described elsewhere herein. The TIM stack may be further bonded to a package component, such as an IHS, for example as described elsewhere herein. Assembly 750 may be further coupled to a board, a substrate, or an interposer 760 along with, one or more of a power management integrated circuit (PMIC) 730, RF (wireless) integrated circuit (RFIC) 725 including a wideband RF (wireless) transmitter and/or receiver (TX/RX) (e.g., including a digital baseband and an analog front end module further comprises a power amplifier on a transmit path and a low noise amplifier on a receive path), and a controller 735.

Functionally, PMIC 730 may perform battery power regulation, DC-to-DC conversion, etc., and so has an input coupled to battery 715 and with an output providing a current supply to other functional modules. As further illustrated, in the exemplary embodiment, RFIC 725 has an output coupled to an antenna (not shown) to implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 4G, and beyond.

While certain features set forth herein have been described with reference to various implementations, this description is not intended to be construed in a limiting sense. Hence, various modifications of the implementations described herein, as well as other implementations, which are apparent to persons skilled in the art to which the present disclosure pertains are deemed to lie within the spirit and scope of the present disclosure.

It will be recognized that the invention is not limited to the embodiments so described, but can be practiced with modification and alteration without departing from the scope of the appended claims. For example the above embodiments may include specific combinations of features as further provided below.

In first examples, a thermal interface material (TIM) stack, comprises a first material comprising carbon and having a first thickness, and a second material over at least one side of the first material. The second material has a second thickness less than the first thickness.

In second examples, for any of the first examples, the first material comprises a filler in a matrix, the filler comprising graphite, and the matrix comprising polymer, the first thickness is at least 50 μm, and the second thickness is less than 5 μm.

In third examples, for any of the second examples the polymer comprises silicone, and the second material has nanostructure.

In fourth examples, for any of the first through third examples the first material has a first bulk modulus, and the second material, in a bulk state, has a second bulk modulus, greater than the first bulk modulus.

In fifth examples, for any of the fourth examples, the first bulk modulus is less than 100 MPa, and the second bulk modulus is more than 10 GPa.

In sixth examples, for any of the first through the fifth examples the second material comprises an elemental metal, or a metal alloy.

In seventh examples, for any of the first through sixth examples, the second material melts, or sinters with at least one of Ni, Cu, Ag, or Au, at less than 300° C.

In eighth examples, for any of first through sixth examples the second material melts, or sinters with at least one of Ni, Cu, Ag, or Au, at less than 200° C.

In ninth examples, for any of the sixth examples the second material comprises at least one of Au, Ag, In, Bi, Ga, or Sn.

In tenth examples, for any of the first through ninth examples, the first material is a pad having a first area, the second material is only on one side of the first material that has the first area, and the second material has at least the first area.

In eleventh examples, for any of the first through the tenth examples, the second material is also on a sidewall of the first material.

In twelfth examples, an integrated circuit (IC) assembly comprises an IC die, a heat spreader, and a thermal interface material (TIM) stack between the IC die and the heat spreader. The TIM stack further comprises a first material, and a second material between the first material and the heat spreader, the second material sintered to the heat spreader.

In thirteenth examples, for any of the twelfth examples the first material has a first thickness, and the second material has a second thickness, less than the first thickness.

In fourteenth examples, for any of the twelfth through thirteenth examples the first material comprises a filler in a matrix, the filler comprising graphite, and the matrix comprising polymer, the first thickness is at least 50 μm, and the second thickness is less than 5 μm.

In fifteenth examples, for any of the twelfth through fourteenth examples the heat spreader comprises at least one of Cu, Ag, or Ni, and the second material comprises an elemental metal or metal alloy.

In sixteenth examples for any of the twelfth through fourteenth examples the second material comprises nanoparticles of the elemental metal or metal alloy.

In seventeenth examples for any of the twelfth through sixteenth examples the second material comprises at least one of Au, Ag, In, Bi, Ga, or Sn.

In eighteenth examples, for any of the twelfth through seventeenth examples the first material has a bulk modulus no more than 10 MPa.

In nineteenth examples, for any of the twelfth through eighteenth examples the second material comprises an elemental metal, or a metal alloy that, in a bulk state, has a bulk modulus exceeding 10 GPa.

In twentieth examples, for any of the twelfth through nineteenth examples the IC die has a first surface of a first area, the first material has a second surface in contact with the first surface, the second surface having a second area, the second material is in contact with the first material, and the second material has a third surface of a third area that is no smaller than the second area, and the heat spreader has a fourth surface in contact with the third surface, the fourth surface having a fourth area, larger than the third area.

In twenty-first examples, for any of the twentieth examples the second area is smaller than the first area, the third area is equal to the second area, and the third surface is bonded to the fourth surface.

In twenty-second examples, a computer platform comprises a power supply, and the IC assembly of claim 12 coupled to the power supply.

In twenty-third examples, a method of assembling an integrated circuit (IC) package, the method comprising attaching an IC die to a substrate, affixing a first layer of a thermal interface material (TIM) stack to the IC die, and joining a heat spreader to a second layer of the TIM stack.

In twenty-fourth examples, for any of the twenty-third examples joining the heat spreader to the second layer of the TIM stack further comprises a thermal compression process that does not exceed 300° C.

In twenty-fifth examples, for any of twenty-third examples the thermal compression process melts the second layer of the TIM stack, or sinters it to the heat spreader, at a temperature below 200° C.

In twenty-sixth examples, a method of fabricating a thermal interface material (TIM) pad, the method comprises receiving a first material comprising a graphitic filler in a polymer matrix, coating a surface of the first material with a second material that melts, or is sinterable with at least one of Ag, Au, Cu, or Ni, at a temperature below 300° C., and cutting at least the first material into a pad having a predetermined footprint.

In twenty-seventh examples, for any of the twenty-sixth examples coating the surface of the first material with the second material further comprises a liquid deposition process.

In twenty-eighth examples, for any of the twenty-seventh examples the liquid deposition process comprises printing or spraying a liquid comprising at least one of Au, Ag, In, Bi, Ga, or Sn particles.

In twenty-ninth examples, a thermal interface means comprises a first material comprising carbon and having a first thickness, and a second material over at least one side of the first material. The second material has a second thickness less than the first thickness.

In thirtieth examples, an integrated circuit (IC) assembly comprises an IC die, a heat spreader, and a thermal interfacing means between the IC die and the heat spreader. The thermal interfacing means further comprises a first material, and a second material between the first material and the heat spreader, the second material sintered to the heat spreader.

What is claimed is:

1. A thermal interface material (TIM) stack, comprising:
a first material comprising carbon and having a first thickness; and
a second material over at least one side of the first material, the second material having a second thickness less than the first thickness.

2. The TIM stack of claim 1, wherein:
the first material comprises a filler in a matrix, the filler comprising graphite, and the matrix comprising polymer;
the first thickness is at least 50 μm; and
the second thickness is less than 5 μm.

3. The TIM stack of claim 2, wherein the polymer comprises silicone, and the second material has nanostructure.

4. The TIM stack of claim 1, wherein:
the first material has a first bulk modulus; and
the second material, in a bulk state, has a second bulk modulus, greater than the first bulk modulus.

5. The TIM stack of claim 4, wherein:
the first bulk modulus is less than 100 MPa; and
the second bulk modulus is more than 10 GPa.

6. The TIM stack of claim 1, wherein the second material comprises an elemental metal, or a metal alloy.

7. The TIM stack of claim 6, wherein the second material melts, or sinters with at least one of Ni, Cu, Ag, or Au, at less than 300° C.

8. The TIM stack of claim 6, wherein the second material melts, or sinters with at least one of Ni, Cu, Ag, or Au, at less than 200° C.

9. The TIM stack of claim 6, wherein the second material comprises at least one of Au, Ag, In, Bi, Ga, or Sn.

10. The TIM stack of claim 1, wherein:
the first material is a pad having a first area;
the second material is only on one side of the first material that has the first area; and
the second material has at least the first area.

11. The TIM stack of claim 1, wherein the second material is also on a sidewall of the first material.

12. An integrated circuit (IC) assembly, comprising:
an IC die;
a heat spreader; and
a thermal interface material (TIM) stack between the IC die and the heat spreader, wherein the TIM stack further comprises:
a first material; and
a second material between the first material and the heat spreader, the second material sintered to the heat spreader.

13. The IC assembly of claim 12, wherein the first material has a first thickness, and the second material has a second thickness, less than the first thickness.

14. The IC assembly of claim 13, wherein:
the first material comprises a filler in a matrix, the filler comprising graphite, and the matrix comprising polymer;
the first thickness is at least 50 μm; and
the second thickness is less than 5 μm.

15. The IC assembly of claim 12, wherein:
the heat spreader comprises at least one of Cu, Ag, or Ni; and
the second material comprises an elemental metal or metal alloy.

16. The IC assembly of claim 15, wherein the second material comprises nanoparticles of the elemental metal or metal alloy.

17. The IC assembly of claim 15, wherein the second material comprises at least one of Au, Ag, In, Bi, Ga, or Sn.

18. The IC assembly of claim 11, wherein the first material has a bulk modulus no more than 10 MPa.

19. The IC assembly of claim 12, wherein the second material comprises an elemental metal, or a metal alloy that, in a bulk state, has a bulk modulus exceeding 10 GPa.

20. The IC assembly of 12, wherein:
the IC die has a first surface of a first area;
the first material has a second surface in contact with the first surface, the second surface having a second area;
the second material is in contact with the first material, and the second material has a third surface of a third area that is no smaller than the second area; and
the heat spreader has a fourth surface in contact with the third surface, the fourth surface having a fourth area, larger than the third area.

21. The IC assembly of claim 20, wherein:
the second area is smaller than the first area;
the third area is equal to the second area; and
the third surface is bonded to the fourth surface.

22. A computer platform comprising:
a power supply; and
the IC assembly of claim 12 coupled to the power supply.
